(19) United States
(12) Patent Application Publication
(10) Pub. No.: US 2009/0091487 A1
(43) Pub. Date: Apr. 9, 2009

(54) Spurious Free Dynamic Range Of An Analog To Digital Converter

(75) Inventors: Nagarajan Viswanathan, Bangalore (IN); Nitin Agarwal, Bangalore (IN); Jagannathan Venkataraman, Bangalore (IN); Visvesvaraya Pentakota, Bangalore (IN); Abhaya Kumar, Bangalore (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/867,016

(22) Filed: Oct. 4, 2007

(51) Int. Cl. H03M 1/44

(52) U.S. Cl. 341/155

(57) ABSTRACT

Removing an Nth harmonic (of a fundamental frequency) generated due to non-ideal ADC operation from the output of the ADC. In an embodiment, digital values containing in-phase and quadrature phase components of the Nth harmonic are generated using mathematical operations, scaled using scaling factors, and then subtracted from the (non-ideal) output of the ADC. A continuous-time derivative of the input signal used to generate the quadrature phase component, enabling a same set of scaling factors to be used for the same input irrespective of the sampling frequency. Spurious Free Dynamic Range of the ADC is thus improved.

### BACKGROUND

1. Field of the Invention

The present invention relates generally to Analog to Digital Converters (ADC), and more specifically improving spurious free dynamic range (SFDR) of an analog to digital converter (ADC).

2. Related Art

Analog to Digital Converters (ADCs) are used to generate a sequence of digital codes representing the strength of an input signal at corresponding time instances, and may be implemented in various forms such as successive approximation (SAR) ADC, pipelined ADC, etc., as is well known in the relevant arts.

Spurious-Free Dynamic Range (SFDR) of an ADC generally quantifies the extent to which harmonic contents are present in the output of the ADC. Ideally, the harmonic contents should be absence for the ideal characteristics of an ADC. According to one convention, SFDR is referred to as the ratio of the RMS (root mean squared) amplitude of the carrier frequency (maximum signal component or fundamental frequency) to the RMS value of the next largest noise or harmonic distortion component (component having a frequency an integer number of times the carrier frequency). SFDR may be measured in dBc (decibels with respect to the carrier frequency amplitude) or in dBFS (decibels with respect to the ADC's full-scale range). Under such a definition, SFDR should ideally equal infinite value.

Several factors may contribute to poor (low value) SFDR in an ADC. For example, a sample and hold amplifier (SHA) at the input of an ADC may cause the generation of a third harmonic component (thrice the frequency of the carrier) because of inherent non-linearity. Similarly, sampling switches used in an ADC (or SHA) may also cause a third harmonic to be generated. While such factors may also cause generation of harmonics other than the third harmonic, the third harmonic is often the substantial component degrading the SFDR.

Several aspects of the present invention improve the spurious free dynamic range of an analog to digital converter.

### BRIEF DESCRIPTION OF THE DRAWINGS

The present invention will be described with reference to the following accompanying drawings, which are described briefly below.

FIG. 1A is a block diagram of an analog to digital converter (ADC) in which several aspects of the present invention may be implemented.

FIG. 1B is a diagram depicting partial internal details of a sample and hold amplifier in an embodiment of an ADC.

FIG. 2A is a diagram illustrating an example frequency versus amplitude plot of the output of an ADC.

FIG. 2B is a diagram illustrating example amplitudes of the fundamental frequency and its harmonic components plotted against time.

FIG. 3 is a flowchart illustrating the manner in which undesirable harmonic components generated in an ADC are removed according to an aspect of the present invention.

FIG. 4 is a block diagram of an ADC in an embodiment of the present invention.

FIG. 5 is a diagram illustrating the details of a continuous-time differentiator in an embodiment of the present invention.

FIG. 6 is a block diagram of an example device/system in which the present invention may be implemented.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

An analog to digital converter (ADC) provided according to an aspect of the present invention provides output sampled values, which are free of nth harmonic of a fundamental frequency component generated by the internal operation of the ADC. In an embodiment, an input signal is sampled at various time instances of interest to generate a second set of digital values. As may be appreciated, the second set of digital values may contain both the fundamental frequency component and the undesirable nth harmonic of the fundamental frequency component.

The desired output sampled values may be generated by subtracting a sum of a third set of digital values and a fourth set of digital values from the second set of digital values, wherein the third set of digital values is a result of a mathematical operation on the second set of digital values, wherein the mathematical operation is designed to generate a component of the Nth harmonic of the fundamental frequency, wherein the fourth set of digital values represents a result of the mathematical operation on a fifth set of digital values, and wherein the fifth set of digital values represent a strength of a second signal at the set of time instances, wherein the second signal represents a rate of change of the input signal.

According to another aspect of the present invention, the second signal is obtained by processing the input signal in the analog domain (as against differentiating the corresponding digital-code representation of the input signal in the digital domain). This enables a same set of scaling factors to be used for the same input irrespective of the sampling frequency.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well known structures or operations are not shown in detail to avoid obscuring the features of the invention.

### 2. Analog to Digital Converter

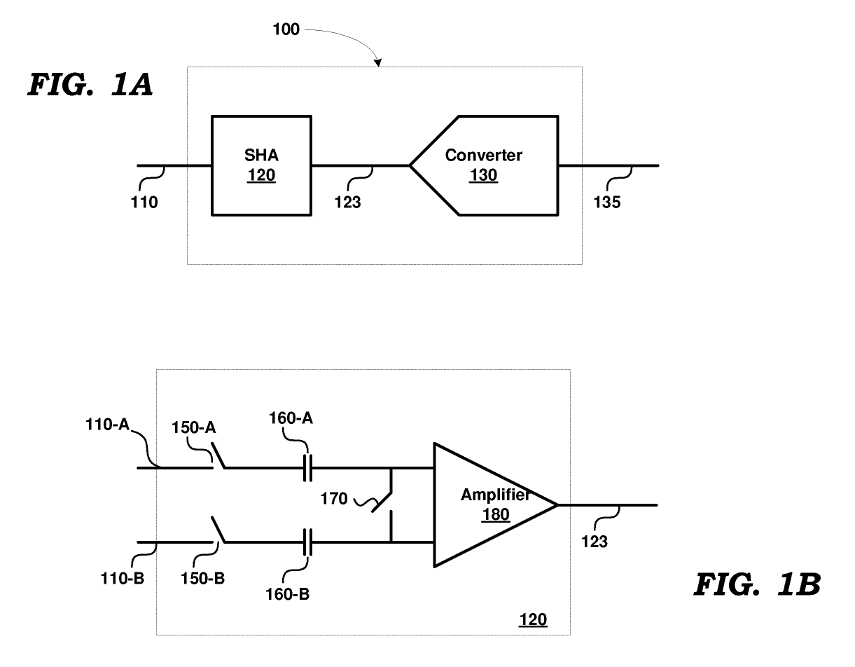

FIG. 1A is a block diagram of an analog to digital converter (ADC) in which several aspects of the present invention may be implemented. ADC 100 is shown containing converter 130 and sample and hold amplifier (SHA) 120. Although shown as separate blocks, SHA 120 and ADC 130 may be implemented as a single block, and the combination as a whole is referred to as ADC 100.

SHA 120 receives an input signal on path 110 (which may be a single-ended or differential path), and samples the input signal at corresponding time instances (often based on sampling edges of a sample clock, not shown). SHA 120 may store the samples generated in a storage element such as a capacitor, as is well known in the relevant arts. SHA 120 provides a stored sample at a corresponding time instance to converter 130 on path 123. It must be understood that the implementation of SHA 120 may be optional, and in some embodiments the input signal 110 may be provided directly to converter 130.

Converter 130 generates digital values (codes) representing the strength of the sample received on path 123, and provides the digital vales on path 135 for further processing (for example, by a digital signal processor, not shown). Thus, each digital value on path 135 represents the strength of the corresponding sample received on path 135. Converter 130 and SHA 120 may be implemented according to any of several well known techniques.

Assuming ADC 100 were ideal, a single (pure) sine wave at input 110 would result in digital codes at output 135 also containing (or representing) only the single sine wave, termed the fundamental (or carrier). However, as noted above, various factors such as non-linearity of SHA 120 or internal operation of converter 130 cause the output codes (path 135) to contain harmonic components of the fundamental as well. The sources of some non-linearities are illustrated with respect to FIG. 1B.

FIG. 1B is a diagram showing partial internal details of SHA 120 in a differential embodiment. Differential input terminals 110-A and 110-B receive an input signal, which is sampled onto sampling capacitors 160-A and 160-B via sampling switches 150-A/150-B and switch 170 (all closed during a sampling interval). Amplifier 180 provides an amplified sample during a hold phase by operation of switches and hold capacitors not shown.

Sampling switches 150-A and 150-B may be non-linear. For example, the signal drop across the switches may not be linearly proportional to the input signal, both in terms of amplitude and frequency. Generally, a higher frequency of the input signal causes a greater degree of non-linearity in switches 150-A and 150-B. As a result, the sampled signal (on capacitors 160-A/160-B) may contain a harmonic of the sine wave input (110-A/110-B) in addition to the fundamental. The harmonic may be in quadrature phase (ninety degrees phase shift) with respect to the fundamental.

Similarly, non-linearities in amplifier 180 may cause generation of harmonic components, which may be in-phase with the fundamental component (used interchangeably with frequency).

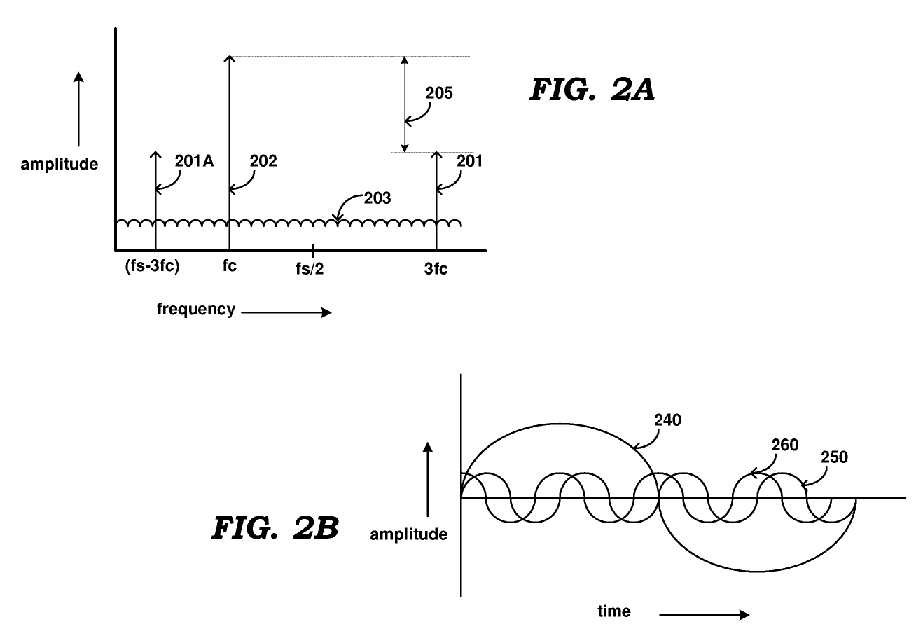

In general, various factors including those noted above, cause the output of ADC 100 to contain undesirable harmonic components of the fundamental frequency, as shown next with respect to FIGS. 2A and 2B.

### 3. Harmonic Components

FIG. 2A is a diagram (not to scale) illustrating an example frequency (X axis) versus amplitude (Y axis) plot of the output 135 (digital codes) of ADC 100. It is assumed that the output shown in FIG. 2A corresponds to an input (on path 110) of a single frequency (fundamental) fc. FIG. 2A is shown containing a fundamental component fc (202) as well as a third harmonic component 201 (or 201A).

Assuming half (fs/2) of the sampling frequency (i.e., half the rate at which samples of input 110 are generated and converted to digital codes) of ADC 100 is greater than thrice the frequency of the fundamental (fc), the third harmonic would appear in output 135 at a frequency 3 times fc (3fc), and is shown marked as 201 in FIG. 2A. However, if fs/2 is less than 3fc, the third harmonic will appear aliased at a frequency (fs-3fc) as denoted by 201A in FIG. 2A.

Waveform 203 represents the noise floor of ADC 100, while 205 represents the SFDR.

In general, the harmonic (3 harmonic 201 or 201A in this example) may contain an in-phase as well as a quadrature component, as noted above, as illustrated in FIG. 2B, which shows the amplitudes of the fundamental and harmonic components, plotted as a function of time.

In FIG. 2B, 240 has a fundamental frequency fc and corresponds to 202 of FIG. 2A, while 250 and 260 are respectively the in-phase and quadrature components of the third harmonic 201 (or 201A) in FIG. 2A.

It must be noted that the input signal may have various harmonics of the fundamental frequency and FIG. 2 would change when such harmonics are considered. For example, if the input signal itself contains a third harmonic (in additional to the fundamental), then the third harmonic at the output will be a sum of the third harmonic at the input and the third harmonic generated by the ADC due to various factors noted above. In such a case, the output may contain other higher order harmonics, such as the 9^{th} harmonic as well.

Several aspects of the present invention enable removal of one or more harmonics (of a fundamental frequency input) generated due to various factors (such as non-linearity etc.) in an ADC, as described next with the help of a flowchart.

### 4. Removing Harmonic Components

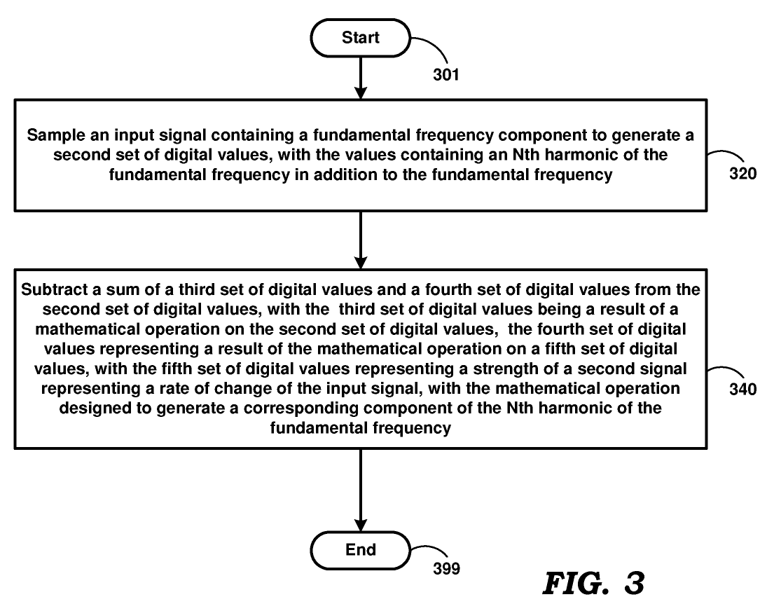

FIG. 3 is a flowchart illustrating the manner in which undesirable harmonic components generated in an ADC are removed in the output digital values (conveniently referred to as a “first set of values”) according to an aspect of the present invention. The flowchart is described with respect to ADC 100 of FIG. 1, merely for illustration. However, various features can be implemented in other environments and other components. Furthermore, the steps are described in a specific sequence merely for illustration.

Alternative embodiments in other environments, using other components and different sequence of steps can also be implemented without departing from the scope and spirit of several aspects of the present invention, as will be apparent to one skilled in the relevant arts by reading the disclosure provided herein. The flowchart starts in step 301, in which control passes immediately to step 320.

In step 320, ADC 100 samples an input signal containing a fundamental frequency component to generate a (second) set of digital values, with the values containing an Nth harmonic of the fundamental frequency in addition to the fundamental frequency. Nth harmonic generally represents the specific harmonic sought to be removed according to an aspect of the present invention. As noted above, the Nth harmonic of the fundamental frequency may be generated in ADC 100 due to the manner in which components/blocks contained in ADC 100 inherently operates, and represents a component that is sought to be removed. Control then passes to step 340.

In step 340, additional circuitry may subtract a sum of a third set (third plurality) of digital values and a fourth set (fourth plurality) of digital values from the second set. The third set of digital values may be obtained by mathematical operation on the second set of digital values, with the mathematical operation designed to generate (a copy) of the Nth harmonic (or a corresponding component of the Nth harmonic) of the fundamental frequency.

For example, assuming the Nth harmonic (noted in step 320) sought to be removed is a third harmonic, the mathematical operation on the second set of digital values is such as to cause (generate) the third set to contain (a copy) of the Nth harmonic. Further, since the input to the mathematical operation is a representation of the input signal itself, the generated copy of the Nth harmonic is in-phase (in-phase component) with the input signal.

The fourth set of digital values represent a result of the mathematical operation on a fifth set of digital values, with the mathematical operation designed to generate (a copy) of the Nth harmonic (or a corresponding component of the Nth harmonic) of the fundamental frequency.

The fifth set of digital values represents strength of a second signal representing a rate of change of the input signal. As noted above, the Nth harmonic may be proportional to frequency of the input signal, with higher frequencies generally causing the Nth harmonic to have a larger amplitude. Since the second signal represents a rate of change of the input signal, its amplitude (and therefore fifth set of digital values) is proportional to the frequency of the input signal. Further, the second signal is phase shifted by ninety degrees with respect to the fundamental frequency of the input signal (by virtue of representing the rate of change of the input signal).

Thus, the mathematical operation on the fifth set of values provides an Nth harmonic component in quadrature phase with respect to the input signal.

It must be understood that, the second, third, fourth and fifth sets of digital values all represent a same portion of the input signal, sampled at a same sampling frequency and the same time instances. Thus, each digital value in the first set has a corresponding digital value in each of the second, third and fourth sets, with each of the values corresponding to a same sampling instant of the input signal.

Subtraction of a sum of the third set of digital values and the fourth set of digital values from the second set of digital values provides a first set of digital values, with the first set representing the input signal free of the Nth harmonic. Control then passes to step 399 in which the flowchart ends.

The features described above can be implemented in various embodiment using different techniques. The description is continued with respect to the details of an example embodiment for illustration.

### 5. Example Embodiment

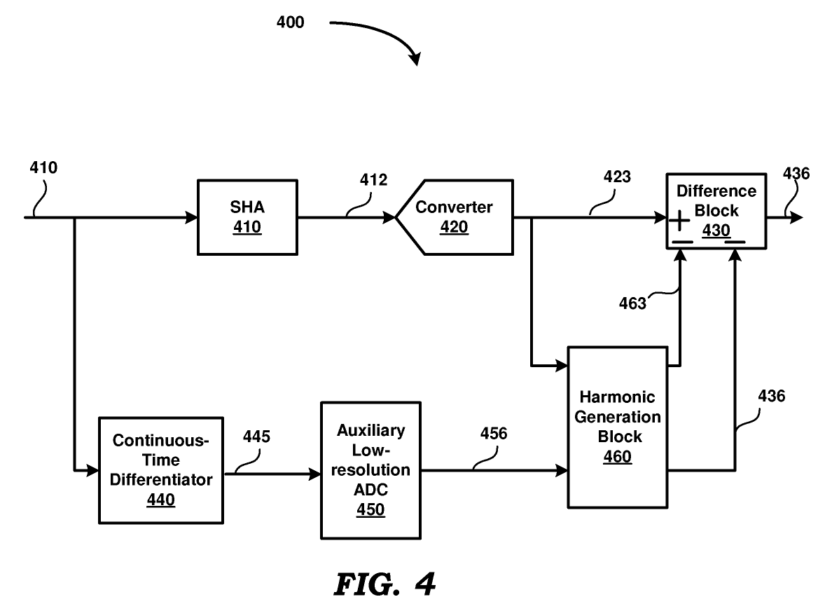

FIG. 4 is a block diagram of an ADC with improved SFDR in an embodiment of the present invention. ADC 400 may be implemented to convert either single-ended or differential signals, and is shown containing sample and hold amplifier (SHA) 410, converter 420, difference block 430, continuous-time differentiator 440, auxiliary low-resolution ADC 450 and harmonic generation block 460. Each component of FIG. 4 is described next in detail.

SHA 410 receives an input signal on path 410 (which may be a single-ended or differential path), and samples the input signal at corresponding time instances (often based on sampling edges of a sample clock, not shown). SHA 410 may store the samples generated in a storage element such as a capacitor, as is well known in the relevant arts. SHA 410 provides a stored sample at a corresponding time instance to converter 420 on path 412. The implementation of SHA 410 may be optional, and in some embodiments the input signal 410 may be provided directly to converter 420.

Converter 420 generates digital values (codes) representing the strength of the sample received on path 412, and provides the digital vales on path 423. Digital values on path 423 a (second set of digital values) represent the strengths of corresponding samples received on path 412. Converter 420 and SHA 410 may be implemented according to any of well known techniques.

Continuous-time differentiator 440 differentiates (in the analog/continuous-time domain) input signal 410 to generate a signal (second signal) on path 445 proportional to the rate of change of input signal 410. Thus, the signal on path 445 contains a component, which is in phase quadrature with a fundamental frequency of the input signal 410.

Auxiliary low-resolution ADC 450 generates digital values (fifth set of digital values) corresponding to the strength of the second signal 445. Auxiliary low-resolution ADC 450 may generate the values corresponding to the same sampling (time) instances used by converter 420 to generate the second set of digital values, as noted above. In an embodiment of the present invention, auxiliary low-resolution ADC 450 is implemented as a flash ADC.

Harmonic generation block 460 receives the digital values on paths 423 and 456, and performs corresponding mathematical operations in the discrete/digital domain to generate (respective components of) the Nth harmonic sought to be eliminated. The specific computations (and operations) to be performed depend on the harmonic(s) sought to be eliminated, and will be apparent to one skilled in the relevant arts by reading the disclosure provided herein.

In an embodiment in which the third harmonic of the fundamental frequency is the dominant harmonic and sought to be eliminated, the mathematical operation corresponds to cubing. Thus, harmonic generation block 460 cubes each value received on path 423 to generate corresponding cubed values on path 463 (third set of digital values). Similarly, harmonic generation block 460 receives the fifth set of values on path 456, and cubes each value to generate corresponding cubed values on path 436 (fourth set of values).

Difference block 430 subtracts a sum of the values received on paths 463 and 436 from the values received on path 423 to generate a set of digital values (first set) on path 436.

Assuming that harmonic generation block implements a ‘cube’ operation (the third harmonic to be eliminated), and that the fundamental frequency of the input signal 410 (and the corresponding digital representation on path 423) is represented by sin(x), cubed values on path 463 represent a signal which may be expressed as given by the following equation:

sin³(x)=(¾)*sin(x)−(¼)*sin(3x) Equation 1

Thus, the digital values on path 463 contain a third harmonic (sin(3x)) of the fundamental of the input signal in-phase with the input signal.

Similarly, the digital values on path 436 contain a third harmonic (cos(3x)) of the fundamental of the input signal in phase quadrature with the input signal since the signal (or a corresponding component) on path 445 is in phase quadrature with the input signal).

Harmonic generation block 460 thus generates in phase and quadrature phase components of the 3d harmonic of the fundamental frequency. Harmonic generation block 460 may multiply the cubed values by a scaling factor such that the generated in phase and quadrature phase components are substantially equal in magnitude to the corresponding components of the 3^{rd} harmonic generated by converter 420 (and/or SHA 410). It may be seen that the subtraction in difference block 430 eliminates the 3^{rd} harmonic component, with the output digital values on path 436 being free of the 3^{rd} harmonic.

The scaling factors may be determined experimentally during testing of converter 420/SHA 410. Several sets of scaling factors may be stored in harmonic generation block 460 (in a memory contained within, but not shown), each set corresponding to a specific process corner or batch of semiconductor die on which converter 420/SHA 410 are fabricated. The specific set of scaling factors to be used may be specified by a user to harmonic generation block 460 by way of an input signal (not shown).

Thus, the third harmonic may be eliminated from the output of ADC 400. As a result. The SFDR of ADC 400 may be improved, and is limited only by the noise floor of ADC 400.

It may also be observed from equation 1 that the outputs of harmonic generation block 460 also contain a fundamental component, which may be cancelled (or at least reduced in strength) by proper selection of scaling factors noted above.

Further, assuming that the input signal itself contains a harmonic in addition to the fundamental, the cubing operation in harmonic generation block 460 may produce harmonic components at the corresponding frequencies as specified by equation 1. It is assumed in this description that such components are sufficiently small in amplitude.

While the foregoing description was made with respect to eliminating the third harmonic, appropriate mathematical operations may be implemented in place of harmonic generation block 460 to achieve elimination of an Nth harmonic in general, as will be readily apparent to one skilled in the relevant arts upon reading the disclosure provided herein. Further, multiple harmonics may also be eliminated simultaneously by selecting mathematical operations to generate the corresponding harmonics (or alternatively, by replicating harmonic generation block 460 with each instance performing a correspondingly different mathematical operation), and by subtracting the resulting harmonics from the output of converter 420.

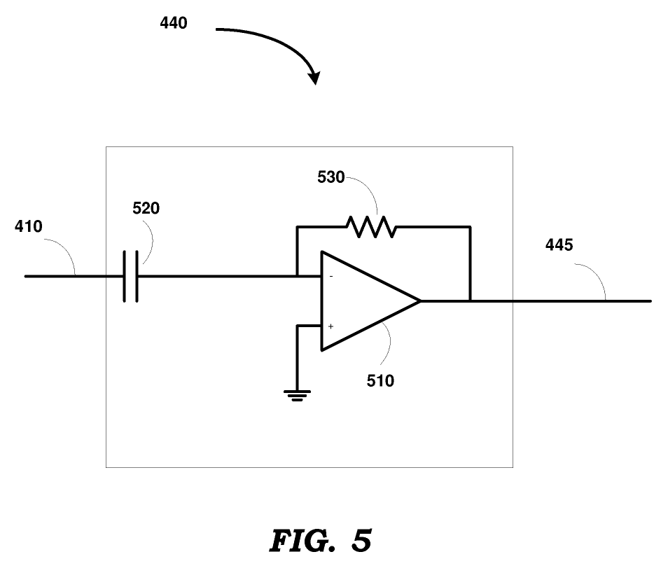

FIG. 5 is a diagram illustrating the details of continuous-time differentiator 440 in an embodiment. OPAMP 510 is connected to capacitor 520 and resistor 530 as shown in the figure to implement a differentiation circuit well known in the relevant arts.

It is also noted here that implementing differentiation in the analog domain (as against differentiating the corresponding digital-code representation of the input signal enables a same set of scaling factors to be used for the same input irrespective of the sampling frequency. On the other hand, when done in digital domain, the differentiator generates an output proportional to the sampling frequency as well, and thus may require different sets of scaling factors for different sampling frequencies.

Further, at least some operations of ADC 400 such as those of harmonic generation block 460 and difference block 430 may, in the alternative, be implemented external to ADC 400. In such a scenario, ADC 400 may contain only SHA 410, converter 420, continuous-time differentiator 440 and auxiliary low-resolution ADC 450, with the operation of difference block 430 and harmonic generation block 460 being performed in a component external to ADC 400 (such as in a processing unit connected to ADC 400).

ADC 400 implemented according to the techniques described above may be incorporated in a system/device, as illustrated next.

### 6. System/Device

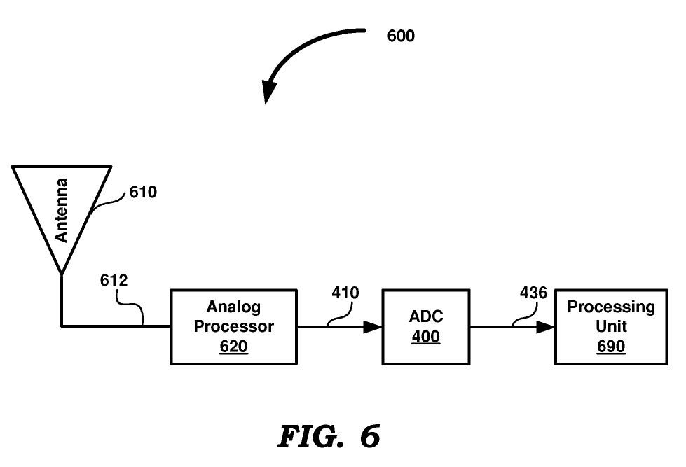

FIG. 6 is a block diagram of receiver system 600 illustrating an example system in which the present invention may be implemented. Receiver system 600, which may correspond to, for example, a mobile phone is shown containing antenna 610, analog processor 620, ADC 400, and processing unit 690. Each component is described in further detail below.

Antenna 610 may receive various signals transmitted over a wireless medium. The received signals may be provided to analog processor 620 on path 612 for further processing. Analog processor 620 may perform tasks such as amplification (or attenuation as desired), filtering, frequency conversion, etc., on received signals and provides the resulting signal on path 410.

ADC 400 converts the analog signal received on path 410 to corresponding digital codes. ADC 400 has an improved (high) SFDR, and may be implemented in a manner described above. ADC 400 provides the digital codes to processing unit 690 on path 436 for further processing. Processing unit 690 receives the recovered data to provide various user applications (such as telephone calls, data applications).

### 7. Conclusion

While various embodiments of the present invention have been described above, it should be understood that they have been presented by way of example only, and not limitation. Thus, the breadth and scope of the present invention should not be limited by any of the above-described embodiments, but should be defined only in accordance with the following claims and their equivalents.

What is claimed is:

1. A method of generating a first plurality of digital values respectively representing a strength of an input signal at a corresponding plurality of time instances, said input signal containing a fundamental frequency component, and said first plurality of digital values being free of an nth harmonic of said fundamental frequency component, said method being performed in an analog to digital converter (ADC), said method comprising:
sampling said input signal at said plurality of time instances to generate a second plurality of digital values, wherein said second plurality of digital values contain both said fundamental frequency component and said nth harmonic of said fundamental frequency component; and
generating said first plurality of digital values by subtracting a sum of a third plurality of digital values and a fourth plurality of digital values from said second plurality of digital values,
wherein said third plurality of digital values is a result of a mathematical operation on said second plurality of digital values, wherein said mathematical operation is designed to generate a component of said nth harmonic of said fundamental frequency component,
wherein said fourth plurality of digital values represents a result of said mathematical operation on a fifth plurality of digital values, wherein said fifth plurality of digital values representing a strength of a second signal at said plurality of time instances, wherein said second signal represents a rate of change of said input signal.

2. The method of claim 1, wherein said nth harmonic is the third harmonic of said fundamental frequency component.

3. The method of claim 2, wherein said generating comprises:
forming said second signal representing a rate of change of said input signal;
sampling said second signal to generate said fifth plurality of digital values representing a strength of said second signal at said plurality of time instances; and
performing said mathematical operation on said fifth plurality of digital values to generate said fourth plurality of digital values.

4. The method of claim 2, wherein said generating further comprises:
performing said mathematical operation on said second plurality of digital values to generate said third plurality of digital values.

5. The method of claim 4, wherein said third plurality of digital values contain an in-phase component of said third harmonic, wherein said fourth plurality of digital values contain a quadrature phase component of said third harmonic.

6. The method of claim 5, wherein said mathematical operation comprises cubing values in each of said third plurality of digital values and said fourth plurality of digital values to obtain respective cubed values, wherein said in-phase component and said quadrature phase component are contained in said respective cubed values.

7. The method of claim 6, wherein each of said cubed values is multiplied by a scaling factor such that said in-phase component and said quadrature phase component contained in said respective cubed values substantially equal corresponding in-phase component and quadrature phase component contained in said second plurality of digital values.

8. The method of claim 1, wherein said second signal is obtained by continuous-time differentiation of said input signal.

9. An analog to digital converter (ADC) for generating a first plurality of digital values respectively representing a strength of an input signal at a corresponding plurality of time instances, said input signal containing a fundamental frequency component, and said first plurality of digital values being free of an nth harmonic of said fundamental frequency component, said ADC comprising:
a converter block to sample said input signal at said plurality of time instances to generate a second plurality of digital values, wherein said second plurality of digital values contain both said fundamental frequency component and said nth harmonic of said fundamental frequency component;
a harmonic generation block to generate a third plurality of digital values and a fourth plurality of digital values,
wherein said third plurality of digital values is a result of a mathematical operation on said second plurality of digital values, wherein said mathematical operation is designed to generate a component of said nth harmonic of said fundamental frequency component,
wherein said fourth plurality of digital values represents a result of said mathematical operation on a fifth plurality of digital values, wherein said fifth plurality of digital values representing a strength of a second signal at said plurality of time instances, wherein said second signal represents a rate of change of said input signal; and
a difference block to generate said first plurality of digital values by subtracting a sum of said third plurality of digital values and said fourth plurality of digital values from said second plurality of digital values.

10. The ADC of claim 9, wherein said nth harmonic is the third harmonic of said fundamental frequency component.

11. The ADC of claim 10, further comprises:
a continuous time differentiator to form said second signal representing a rate of change of said input signal;
an auxiliary ADC to sample said second signal to generate said fifth plurality of digital values representing a strength of a second signal at said plurality of time instances,
wherein said harmonic generation block performs said mathematical operation on said fifth plurality of digital values to generate said fourth plurality of digital values.

12. The ADC of claim 10, wherein said harmonic generation block performs said mathematical operation on said second plurality of digital values to generate said third plurality of digital values.

13. The ADC of claim 12, wherein said third plurality of digital values contain an in-phase component of said third harmonic, wherein said fourth plurality of digital values contain a quadrature phase component of said third harmonic.

14. The ADC of claim 13, wherein said mathematical operation comprises cubing values in each of said third plurality of digital values and said fourth plurality of digital values to obtain respective cubed values, wherein said in-phase component and said quadrature phase component are contained in said respective cubed values.

15. The ADC of claim 14, wherein each of said cubed values is multiplied by a scaling factor such that said in-phase component and said quadrature phase component contained in said respective cubed values equal corresponding in-phase component and quadrature phase component contained in said second plurality of digital values.

16. A device comprising:
a processing unit to process a first plurality of digital values; and
an analog to digital converter (ADC) to generate said first plurality of digital values respectively representing a strength of an input signal at a corresponding plurality of time instances, said input signal containing a fundamental frequency component, and said first plurality of digital values being free of an nth harmonic of said fundamental frequency component, said ADC comprising:
a converter block to sample said input signal at said plurality of time instances to generate a second plurality of digital values, wherein said second plurality of digital values contain both said fundamental frequency component and said nth harmonic of said fundamental frequency component;
a harmonic generation block to generate a third plurality of digital values and a fourth plurality of digital values,
wherein said third plurality of digital values is a result of a mathematical operation on said second plurality of digital values, wherein said mathematical operation is designed to generate a component of said nth harmonic of said fundamental frequency component,
wherein said fourth plurality of digital values represents a result of said mathematical operation on a fifth plurality of digital values, wherein said fifth plurality of digital values representing a strength of a second signal at said plurality of time instances, wherein said second signal represents a rate of change of said input signal; and
a difference block to generate said first plurality of digital values by subtracting a sum of said third plurality of digital values and said fourth plurality of digital values from said second plurality of digital values.

17. The device of claim 16, further comprising an analog processor to receive an analog signal at a first frequency and generating said input signal at a lower frequency than said first frequency, wherein said input signal at said lower frequency is processed by said ADC.

18. The device of claim 16, wherein said ADC further comprises:
a continuous time differentiator to form said second signal representing a rate of change of said input signal;
an auxiliary ADC to sample said second signal to generate said fifth plurality of digital values representing a strength of a second signal at said plurality of time instances,
wherein said harmonic generation block performs said mathematical operation on said fifth plurality of digital values to generate said fourth plurality of digital values.

19. The device of claim 18, wherein said harmonic generation block performs said mathematical operation on said second plurality of digital values to generate said third plurality of digital values.

20. The device of claim 19, wherein said nth harmonic is a third harmonic, wherein said third plurality of digital values contain an in-phase component of said third harmonic, wherein said fourth plurality of digital values contain a quadrature phase component of said third harmonic.
